(19) United States
(12) Patent Application Publication
(10) Pub. No.: US 2011/0070411 A1
(43) Pub. Date: Mar. 24, 2011

(54) PLASTIC WITH IMPROVED GLOSS PROPERTIES AND SURFACE TREATMENT METHOD

(75) Inventors: Yong Jun Jang, Seongnam (KR); Ki Chun Lee, Seoul (KR); Sang Sun Park, Anyang (KR); Kwang Ryeol Lee, Seoul (KR); Myoung Woon Moon, Seoul (KR); Faruque Ahmed Sk, Seoul (KR)

(73) Assignees: HYUNDAI MOTOR COMPANY, Seoul (KR); KIA MOTORS CORPORATION, Seoul (KR); KOREA INSTITUTE OF SCIENCE AND TECHNOLOGY, Seoul (KR)

(21) Appl. No.: 12/732,376

(22) Filed: Mar. 26, 2010

(30) Foreign Application Priority Data
Sep. 23, 2009 (KR) 10-2009-0090292

(51) Int. Cl. B32B 3/10; C23C 14/48; C23C 14/12

(52) U.S. Cl. 428/195.1; 427/526; 427/525

(57) ABSTRACT

The present invention provides a plastic with improved gloss properties and a surface treatment method for plastic, which forms a nanopattern and a hardened layer on the surface of a polymer material by irradiating an argon ion beam onto the surface to change the refractive index, thus changing the gloss of the polymer variously using only the polymer/plastic material.

### CROSS-REFERENCE TO RELATED APPLICATION

This application claims under 35 U.S.C. §119(a) the benefit of Korean Patent Application No. 10-2009-0090292 filed Sep. 23, 2009, the entire contents of which are incorporated herein by reference.

### BACKGROUND

(a) Technical Field

The present disclosure relates, generally, to a plastic with improved gloss properties and a method for preparing the same. More particularly, it relates to a plastic with improved gloss properties and to a surface treatment method for plastic, which can change the intrinsic color of polymer into various glosses.

(b) Background Art

Many types of plastics are widely used in manufacturing a variety of parts due to qualities such as excellent moldability, lightweight, and relatively low price. However, many types of plastics also have low surface hardness and undesirable external appearance and are vulnerable to scratch.

Polypropylene in particular is widely used in various fields due to certain advantages such as its relatively stable price, it is lightweight, and it has excellent mechanical strength; however, it also has low impact resistance and strength properties.

Accordingly, a polypropylene resin composition, in which ethylene-propylene copolymer rubber (EPM) and an inorganic filler such as talc are added, has been provided. However, these molded products have an undesirable external appearance and should preferably be subjected to a painting process after molding.

Further, since propylene has a non-polar group in the molecule, it is chemically inactive, and thus the paintability is not good. Therefore, there remains a need to improve the paintability.

There are a variety of surface treatment methods for improving the paintability.

For example, metal plating such as chrome plating and nickel plating is widely used at present.

Chrome plating, for example, preferably includes a process of non-electrolytic plating the surface of the plastic molded product with copper and a process of electrolytic plating the thus obtained conductive film with chrome.

However, the chrome plating process is complicated, the cost is high, and it is harmful to environment.

Moreover, there are certain limitations in providing various surface textures.

The above information disclosed in this Background section is only for enhancement of understanding of the background of the invention and therefore it may contain information that does not form the prior art that is already known in this country to a person of ordinary skill in the art.

### SUMMARY OF THE DISCLOSURE

In one aspect, the present invention preferably provides a plastic with improved gloss properties and a surface treatment method for plastic, which preferably forms a nanopattern and a hardened layer on the surface of polypropylene by irradiating an argon ion beam onto the surface, thus suitably changing the gloss of the polymer using only the polymer/plastic material.

In one preferred embodiment, the present invention provides a plastic preferably including a nanopattern and a hardened layer that is suitably formed by irradiating an ion beam onto the surface of a polymer material to have suitably high gloss properties.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The above features and advantages of the present invention will be apparent from or are set forth in more detail in the accompanying drawings, which are incorporated in and form a part of this specification, and the following Detailed Description, which together serve to explain by way of example the principles of the present invention.

The above and other features of the invention are discussed infra.

### BRIEF DESCRIPTION OF THE DRAWINGS

The above and other features of the present invention will now be described in detail with reference to certain exemplary embodiments thereof illustrated the accompanying drawings which are given hereinbelow by way of illustration only, and thus are not limitative of the present invention, and wherein:

FIG. 1 is schematic diagram showing an exemplary nanopattern and a surface hardened layer formed by ion-plasma treatment in accordance with one preferred Example of the present invention;

FIG. 2A is a scanning electron microscope (SEM) image of the surface of polypropylene (PP) treated at a voltage of 1,000 eV for five minutes by argon ion-plasma in the Example embodiment of FIG. 1;

FIG. 2B is a graph showing a change in roughness of the nanopattern obtained by suitably changing the treatment time at a fixed voltage of 1,000 eV in the Example of FIG. 1;

FIG. 2C is an SEM image of the surface of PP treated at 20 keV for five minutes in the Example of FIG. 1;

FIG. 2D is an SEM image of the surface of PP treated at 20 keV for five minutes on which a hardened surface is suitably formed in the Example of FIG. 1;

FIG. 3 shows the results of Raman analysis on the surface hardened layer of PP formed by argon ion-plasma in the Example of FIG. 1;

FIGS. 4A and 4B show the results of FT-IR analysis on the surface hardened layer of PP formed by a change in argon plasma energy in the Example of FIG. 1;

FIGS. 5A and 5B show the results of FT-IR analysis on the surface hardened layer of PP obtained at a fixed argon plasma energy of 1,000 eV and by changing the plasma treatment time in the Example of FIG. 1; and

FIGS. 5C and 5D show the results of FT-IR analysis on the surface hardened layer of PP obtained by changing the argon plasma energy from 10 to 50 keV in the Example of FIG. 1.

Reference numerals set forth in the Drawings includes reference to the following elements as further discussed below:
10: surface hardened layer 20: polymer material

It should be understood that the appended drawings are not necessarily to scale, presenting a somewhat simplified representation of various preferred features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

As described herein, the present invention includes a plastic comprising a nanopattern and a hardened layer formed by irradiating an ion plasma onto the surface of a polymer material.

In preferred embodiments, the plastic has high gloss properties.

The present invention also features a surface treatment method for plastic comprising forming a nanopattern and a hardened layer by irradiating an ion plasma onto the surface of a polymer material.

In one embodiment, the depths of the nanopattern and the hardened layer are adjusted by controlling at least one of the irradiation time, the voltage, and the pressure in a treatment chamber during the ion-plasma treatment.

In another embodiment, the polymer material comprises a plastic selected from polypropylene (PP), Nylon 6, Nylon 66, polycarbonate (PC), polyimide (PI), polystyrene (PS), polyethylene (PE), polymethylmethacrylate (PMMA), polydimethylsiloxane (PDMS), poly(lactic-co-glycolic acid) (PLGA), hydrogel, polyethylene terephthalate (PET), and silicone rubber, or a plastic mixture selected from the group consisting of PC/ABS, PC/SAN, and PC/PBT.

In another further embodiment, the nanopattern and the hardened layer are formed on the surface of the polymer material by irradiating an ion plasma.

In a further embodiment, the nanopattern and the hardened layer are formed on the surface of the polymer material by irradiating an ion beam.

In still another embodiment, the nanopattern and the hardened layer are formed on the surface of the polymer material by irradiating a plasma.

The present invention also features a plastic formed by the surface treatment method described herein.

Hereinafter reference will now be made in detail to various embodiments of the present invention, examples of which are illustrated in the accompanying drawings and described below. While the invention will be described in conjunction with exemplary embodiments, it will be understood that present description is not intended to limit the invention to those exemplary embodiments. On the contrary, the invention is intended to cover not only the exemplary embodiments, but also various alternatives, modifications, equivalents and other embodiments, which may be included within the spirit and scope of the invention as defined by the appended claims.

According to certain preferred embodiments, the present invention provides a plastic with improved gloss properties and a surface treatment method for plastic, which suitably forms a nanopattern and a hardened layer on the surface of polypropylene by irradiating an argon ion beam onto the surface, thus suitably changing the gloss of the polymer variously using only the polymer/plastic material.

According to preferred embodiments of the present invention, the plastic surface is preferably treated by argon, nitrogen, or oxygen ion plasma using an ion-plasma treatment method to suitably form a nanopattern having a width of 1 to 1,000 nm and a length of 1 to 10,000 nm and a surface hardened layer having a thickness of 0.1 to 1,000 nm, thus suitably changing the gloss of the plastic surface.

For example, according to certain exemplary embodiments of the present invention, when an argon ion beam is suitably irradiated onto the surface of polypropylene (PP), the surface of PP reacts with the ion plasma, and preferably a nanopattern and a hardened layer 10 are suitably simultaneously formed on the surface of PP.

Accordingly, in further preferred embodiments, by the nanopattern and hardened layer 10 formed on the plastic surface, it is possible to suitably change the intrinsic color of polymer into various glosses, and thus the plastic product can be used in various fields such as, but not limited only to, interior and exterior materials for vehicles, cellular phones, home electronic appliances, etc.

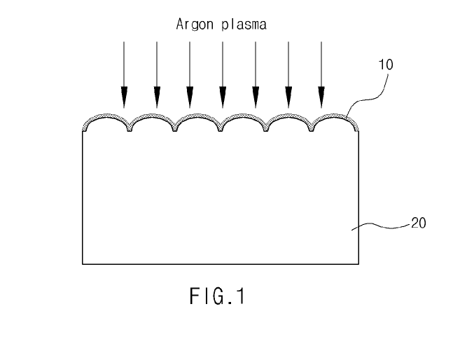

According to certain exemplary embodiments of the invention, for example as shown in FIG. 1, FIG. 1 is schematic diagram showing an exemplary nanopattern and a surface hardened layer 10 formed on the flat surface of polypropylene by ion-plasma treatment in accordance with a preferred Example of the present invention.

Preferably, referring to FIG. 1 for example, ion-plasma treatment is suitably performed on the surface of PP as a polymer material 20 using a broad ion beam to form a nanopattern.

In further preferred embodiments, the ion-plasma treatment uses a gas selected from the group consisting of, but not necessarily only limited to, argon, oxygen, nitrogen, helium, and carbon tetrafluoride (CF₄) formed by plasma ionization. In other preferred embodiments, the nanopattern may be suitably formed on the polymer surface by implanting the ion plasma into the polymer surface using an ion beam method, a method of forming a thin film, or a method of sputtering metal and non-metal materials.

According to other certain exemplary embodiments of the present invention, the depths of the nanopattern and the hardened layer 10 can be suitably adjusted by controlling at least one of the irradiation time of the ion beam, the magnitude of the acceleration voltage, and the pressure in a treatment chamber.

According to certain preferred embodiments, the conditions for forming the nanopattern are described herein as follows. The pressure in the treatment chamber in which the ion-plasma treatment is performed is in a range of 1.0×10⁻⁷ to 2.75×10⁻³ Pa, the magnitude of the acceleration voltage of the ion-plasma applied during the ion-plasma treatment is in a range of 100 V to 50 kV, the irradiation time of the ion beam during the ion-plasma treatment is several seconds to several hours, and the incident angle of the ion beam during the ion-plasma treatment is 90° with respect to the polymer surface in the exemplary embodiment of the present invention, preferably in a range of 0 to 90°.

Preferably, when an ion beam of low energy (e.g., 1 kV) is suitably irradiated onto the surface of the polymer material, the nanopattern and the hardened layer are simultaneously formed, whereas when an ion beam of high energy (e.g., more than 10 kV) is irradiated onto the surface of the polymer material, only the hardened layer is suitably formed.

Accordingly, in the case of the low energy, the gloss properties are suitably improved by a nanostructure wherein the hardened layer is formed, and in the case of the high energy, the gloss properties are suitably improved only by the hardened layer.

According to other exemplary embodiments of the present invention, besides the polypropylene, the polymer material 20 may be a plastic selected from the group consisting of, but not necessarily limited to, polyethylene (PE), Nylon 6, Nylon 66, polycarbonate (PC), polyimide (PI), polymethylmethacrylate (PMMA), polystyrene (PS), poly(lactic-co-glycolic acid) (PLGA), hydrogel, polyethylene terephthalate (PET), silicone rubber, and polydimethylsiloxane (PDMS) or a plastic mixture selected from the group consisting of PC/ABS, PC/SAN, and PC/PBT, which could have a nanoscale roughness on the surface thereof.

The present invention will be described in more detail with reference to the following Examples; however, the present invention is not limited only to the Examples described herein.

### EXAMPLE

In one preferred example, a nanopattern and a nanosized hardened layer 10 were suitably formed on the surface of PP by irradiating argon plasma thereto in accordance with an Example of the present invention.

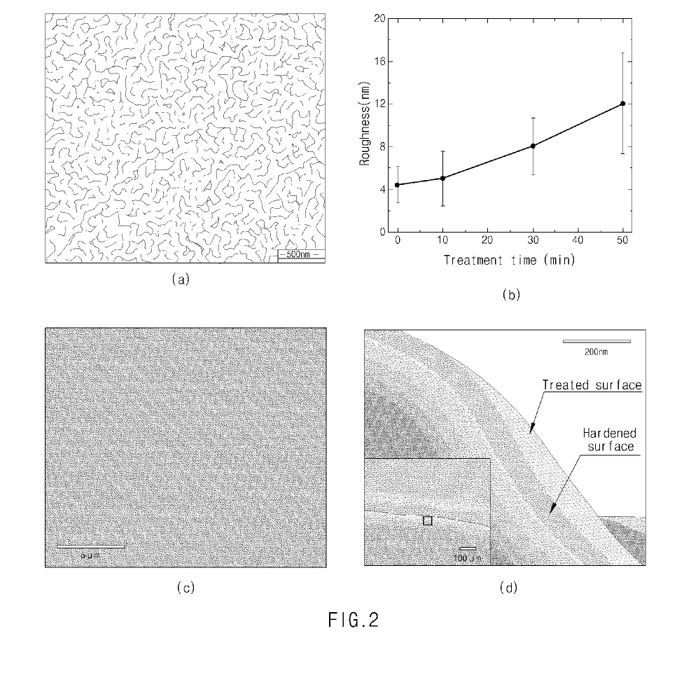

FIG. 2A is a scanning electron microscope (SEM) image obtained by suitably performing an ion beam treatment on the surface of PP in the Example of FIG. 1 and FIG. 2B is a graph showing a change in roughness of the nanopattern, from which it can be seen that the roughness of the pattern was gradually increased by an increase in the irradiation time of argon beam.

According to further exemplary embodiments, the polypropylene (PP) was purchased from LG Chemical Ltd., and a translucent material was preferably used. Preferably, the direction of the ion plasma treatment is fixed vertically with respect to the surface of the PP sample.

Argon (Ar⁺) ion-plasma treatment was preferably performed on the surface of the PP sample as the polymer material 20 having a flat surface.

According to further preferred embodiments, the voltage between the cathode and anode of an ion gun was 1,000 eV, the treatment time was preferably changed from five minutes to two hours, and the working vacuum in the treatment chamber was preferably below 0.01 mTorr.

According to further exemplary embodiments, the change in the surface hardened layer 10 according to a change in the total plasma energy from 10 to 50 keV was examined.

Preferably, when the polymer surface is treated using ion or plasma, the polymer chains on the soft polymer surface are suitably rearranged, the C—H bond on each polymer chain is suitably broken, and the amount of C—C bonds is suitably increased, which results in a hardening of the polymer surface.

At the same time, deformation occurs in the film surface direction on the hardened surface, and thus the surface pattern is suitably formed to mitigate the deformation.

According to further exemplary embodiments, for example as shown in FIGS. 2A and 2B, the width and height of the nanopattern had a close relation to the change in the plasma treatment time, i.e., the amount of ions and, when the plasma treatment time was suitably increased, the roughness of the polymer surface increased.

Further, in other preferred embodiments, for example as shown in FIGS. 2C and 2D, although the surface pattern was not suitably formed when the ion-plasma energy was 20 keV, a surface hardened layer 10 having a depth of about 100 nm was suitably formed to improve the refractive index.

### Test Example: Surface Analysis

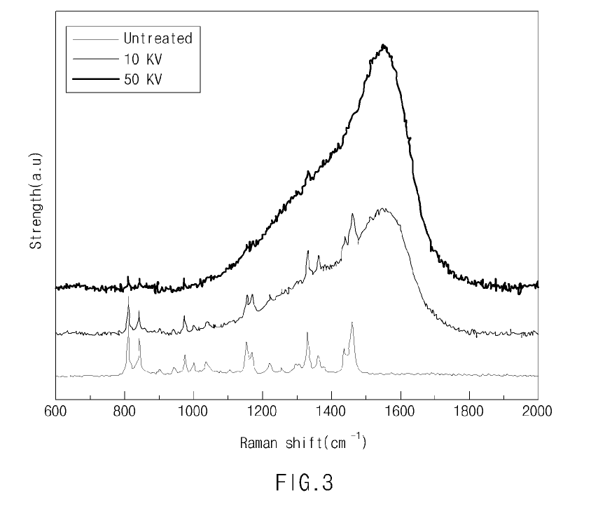

According to certain exemplary embodiments, and as shown in FIG. 3, FIG. 3 shows the results of Raman analysis on the surface hardened layer of PP before and after the ion-plasma treatment, which shows the change in the chemical bonding strength.

Preferably, while the surface of the PP sample before the ion-plasma treatment shows typical properties of amorphous polymer, the surfaces of the PP samples after the ion-plasma treatment exhibit D (disordered graphitic) peaks at a wave number of about 1,365 cm⁻¹ and G (crystalline graphitic) peaks at about 1,540 cm⁻¹, which are typically present in an amorphous carbon thin film.

Accordingly, it can be seen that the soft polymer surface was suitably changed into an amorphous carbon layer having considerable hardness by the ion-plasma treatment.

Further, it can be inferred that the electrical conductivity of the polymer surface was simultaneously changed by the ion-plasma treatment.

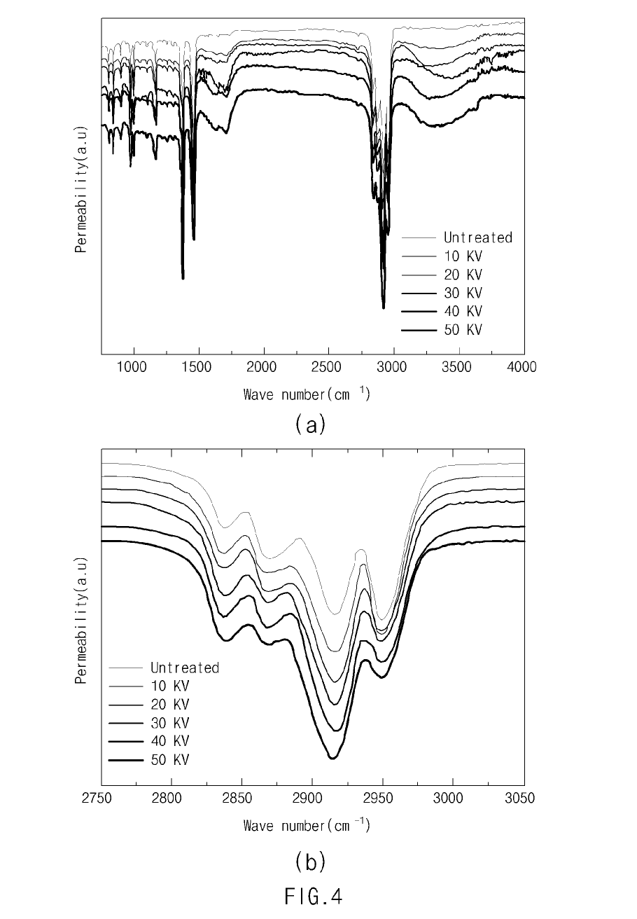

According to other further embodiments, for example as shown in FIG. 4, FIGS. 4A and 4B show the results of FT-IR analysis on the surface hardened layer of PP before and after the ion-plasma treatment, in which the change in the permeability is shown.

In FIGS. 4A and 4B, the amount of C-Hn bonds at about 2,800 cm⁻¹ was suitably changed in proportion to the ion beam treatment time.

In particular preferred embodiments, while the amount of CH₂ bonds was suitably increased by the increase in the ion-plasma energy, the amount of CH₃ bonds was suitably decreased, from which it can be seen that the cross-linking of the polymer chains occurred more actively than the scission of the polymer chains.

Accordingly, it can be estimated that the cross-linking properties were suitably increased in the area affected by the ion-plasma, and the corresponding area was suitably hardened.

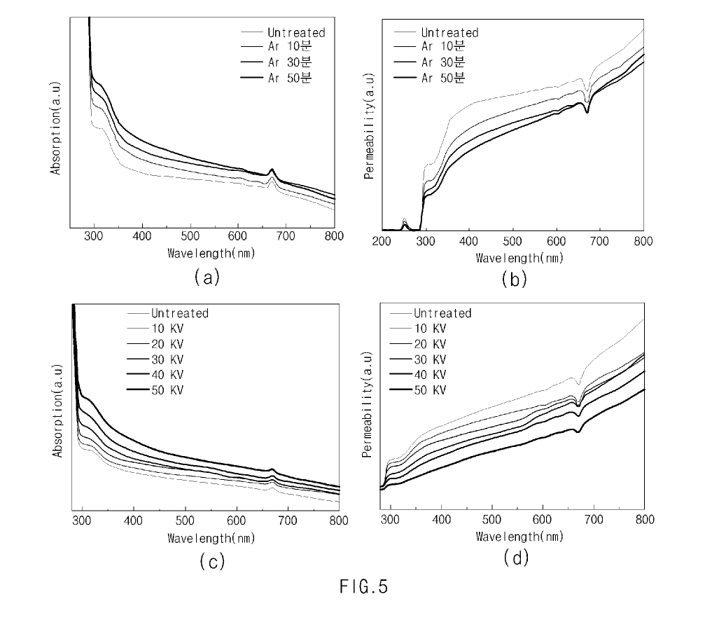

According to other further embodiments, for example as shown in FIG. 5, FIGS. 5A to 5D show the results of FT-IR analysis using UV-VIS spectrophotometer, in which the change in the permeability and the change in the absorption before and after the ion-plasma treatment are shown.

The absorption was increased as shown in FIG. 5A and the permeability was decreased as shown in FIG. 5B by the change in the treatment time at a fixed voltage of 1,000 eV.

In further exemplary embodiments, the absorption and the permeability were suitably analyzed by changing the argon plasma energy, from which it can be seen that the absorption was suitably increased as shown in FIG. 5C and the permeability was decreased as shown in FIG. 5D by the increase in the plasma energy.

Accordingly, these properties suitably change the intrinsic absorption and permeability that the polymer has and thus change the intrinsic optical properties of the polymer such as the refractive index, which results in a change in the gloss.

Therefore, according to preferred embodiments of the present invention as described herein, it is possible to adjust the absorption and permeability of light by changing the surface treatment time and energy of the ion-plasma treatment, thus providing various glosses on the polymer surface.

As described above, plastic with improved gloss properties and the surface treatment method for plastic in accordance with preferred embodiments of the present invention described herein include, but are not limited to, the following advantages and effects. The present invention provides various glosses from the intrinsic color of polymer by suitably forming a nanopattern and a hardened layer on the plastic surface by ion-plasma treatment. In the present invention, since it is not necessary to coat the plastic surface with metal, for example, the process is suitably simplified and environmentally-friendly compared to conventional methods for providing high gloss polymer.

The invention has been described in detail with reference to preferred embodiments thereof. However, it will be appreciated by those skilled in the art that changes may be made in these embodiments without departing from the principles and spirit of the invention, the scope of which is defined in the appended claims and their equivalents.

What is claimed is:

1. A plastic comprising a nanopattern and a hardened layer formed by irradiating an ion plasma onto the surface of a polymer material to have high gloss properties.

2. A surface treatment method for plastic comprising forming a nanopattern and a hardened layer by irradiating an ion plasma onto the surface of a polymer material.

3. The method of claim 2, wherein the depths of the nanopattern and the hardened layer are adjusted by controlling at least one of the irradiation time, the voltage, and the pressure in a treatment chamber during the ion-plasma treatment.

4. The method of claim 2, wherein the polymer material comprises a plastic selected from the group consisting of polypropylene (PP), Nylon 6, Nylon 66, polycarbonate (PC), polyimide (PI), polystyrene (PS), polyethylene (PE), polymethylmethacrylate (PMMA), polydimethylsiloxane (PDMS), poly(lactic-co-glycolic acid) (PLGA), hydrogel, polyethylene terephthalate (PET), and silicone rubber, or a plastic mixture selected from the group consisting of PC/ABS, PC/SAN, and PC/PBT.

5. The method of claim 2, wherein the nanopattern and the hardened layer are formed on the surface of the polymer material by irradiating an ion plasma.

6. The method of claim 2, wherein the nanopattern and the hardened layer are formed on the surface of the polymer material by irradiating an ion beam.

7. The method of claim 2, wherein the nanopattern and the hardened layer are formed on the surface of the polymer material by irradiating a plasma.

8. A plastic formed by the surface treatment method of claim 2.

9. A plastic comprising a nanopattern and a hardened layer formed by irradiating an ion plasma onto the surface of a polymer material.

10. The plastic of claim 9, wherein the plastic has high gloss properties.
